(19) United States
(12) Patent Application Publication
(10) Pub. No.: US 2009/0263960 A1
(43) Pub. Date: Oct. 22, 2009

(54) SEMICONDUCTOR DEVICE WITH RECESS GATE AND METHOD OF FABRICATING THE SAME

(75) Inventor: Young-Kyun JUNG, Kyoungki-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: Hynix Semiconductor Inc., Kyoungki-do (KR)

(21) Appl. No.: 12/492,775

(22) Filed: Jun. 26, 2009

Related U.S. Application Data
(62) Division of application No. 11/644,883, filed on Dec. 26, 2006.

(30) Foreign Application Priority Data
Jun. 30, 2006 (KR) 10-2006-0060293

(51) Int. Cl. H01L 21/28

(52) U.S. Cl. 438/589; 257/E21.19

(57) ABSTRACT

A semiconductor device with a recess gate includes a substrate, a semiconductive layer having an opening corresponding to a gate region, a gate electrode filled in the opening, and a gate insulating layer interposed between the gate electrode and the substrate, and between the gate electrode and the semiconductive layer.

### CROSS-REFERENCE TO RELATED APPLICATIONS

The present invention claims priority of Korean patent application number 10-2006-0060293, filed on Jun. 30, 2006, which is incorporated by reference in its entirety.

### BACKGROUND OF THE INVENTION

The present invention relates to a semiconductor fabrication technology, and more particularly, to a method of fabricating a semiconductor device with a recess gate.

Recently, with the high integration of semiconductor memory devices, the devices shrink in size and patterns become fine. As the size of the device becomes smaller, a gate channel length is also reduced so that an operational speed or input/output rate of information becomes slower due to a leakage current caused by short channel effect, hot carrier effect, and so on. To prevent this limitation, various structured recess gates have been proposed for securing a sufficient channel length.

FIG. 1 illustrates a cross-sectional view of a typical method of fabricating a semiconductor device with a recess gate. A device isolation structure 12 is formed in a given region of a substrate 11 to define an active region. The active region of the substrate 11 is selectively etched to form a recess 13. A gate insulating layer 14 is formed on an inner surface of the recess 13. A gate polysilicon layer 15 is deposited over the gate insulating layer 14 such that the gate polysilicon layer 15 fills the recess 13 and has a protrusion structure higher than the surface of the substrate 11. A gate metal layer 16 is formed over the gate polysilicon layer 15 to form a recess gate RG.

According to the typical method, a channel length is increased by virtue of the recess 13 formed by etching the substrate 11 using a recess mask. The typical method such as a recess etch process; however, directly etches the substrate in forming the recess, which has an impact on the substrate. Thus, dangling bonds may occur and have an adverse effect on the device.

To reduce such adverse effect, an oxidation process may be performed. But also, an oxide layer is not uniformly formed so that the oxide layer may still have a detrimental effect on a channel. In this case, another etching process may be performed on the substrate for removing surface roughness thereof (see FIG. 2) which increases overall fabrication process steps.

FIG. 2 illustrates a cross-sectional view showing a limitation of a typical method of forming a recess gate in a semiconductor device. Since there occurs a limitation such as dangling bonds in the substrate before light etch treatment (LET) process, these dangling bonds may have a detrimental effect on the channel even after source/drain regions are formed. An etching process could be performed to remove the rough surface of the recess, but this would increase the overall process steps, as described above.

### SUMMARY OF THE INVENTION

Embodiments of the present invention are directed to provide a semiconductor device including a recess gate with a reduced limitation such as a dangling bond by not employing a recess etch process, and a method for fabricating the same.

In accordance with an aspect of the present invention, there is provided a semiconductor device with a recess gate, including: a substrate; a semiconductive layer having an opening corresponding to a gate region; a gate electrode filled in the opening; and a gate insulating layer interposed between the gate electrode and the substrate, and between the gate electrode and the semiconductive layer.

In accordance with another aspect of the present invention, there is provided a method of fabricating a semiconductor device with a recess gate, the method including: forming a sacrificial pattern over a given region of a substrate; forming a semiconductive layer on the resultant structure including the sacrificial pattern; planarizing the semiconductive layer until the sacrificial pattern is exposed; removing the sacrificial pattern to form an opening; forming a gate insulating layer in the opening and over the substrate; forming a gate conductive layer over the gate insulating layer; and planarizing the gate conductive layer until the gate insulating layer is exposed.

### BRIEF DESCRIPTION OF THE DRAWINGS

FIG. 1 illustrates a cross-sectional view showing a typical method for fabricating a semiconductor device with a recess gate.

FIG. 2 illustrates cross-sectional views showing a limitation of a typical method for forming a recess gate in a semiconductor device.

FIG. 3 illustrates a cross-sectional view showing a semiconductor device with a recess gate in accordance with an embodiment of the present invention.

FIGS. 4A to 4G illustrate cross-sectional views showing a method for fabricating the semiconductor device with the recess gate in accordance with an embodiment of the present invention.

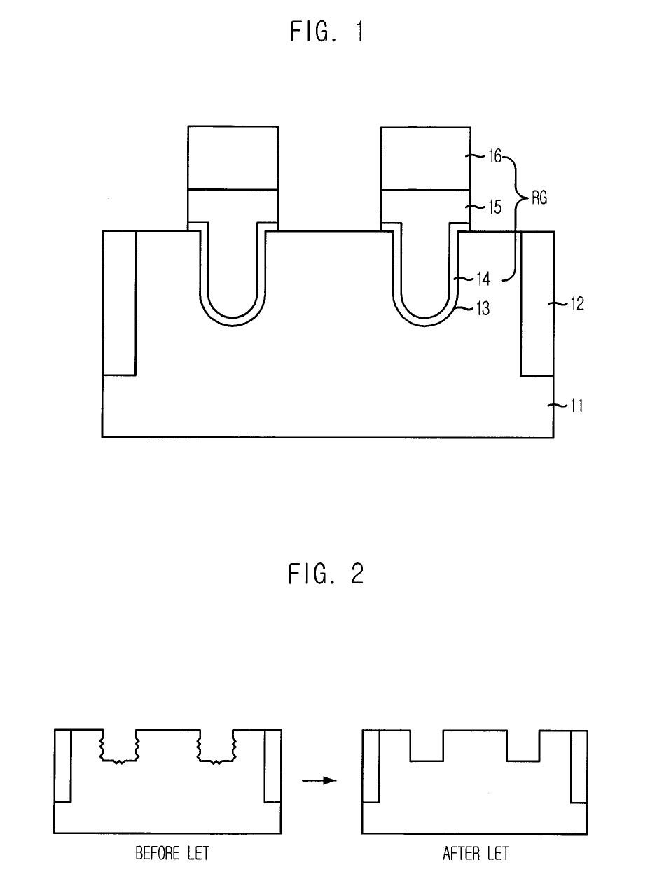

### DESCRIPTION OF SPECIFIC EMBODIMENTS

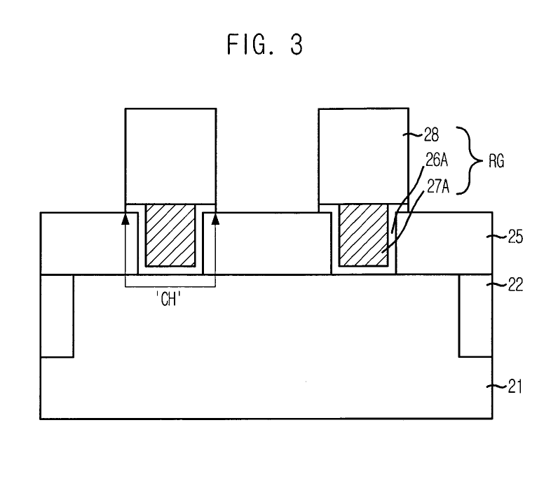

FIG. 3 illustrates a cross-sectional view showing a semiconductor device with a recess gate in accordance with an embodiment of the present invention. A device isolation structure 22 is formed in a substrate 21 to define an active region and a field region. A silicon pattern 25 is formed on the substrate 21, wherein the silicon pattern 25 has an opening corresponding to a region where a gate will be formed. A first gate electrode 27A is filled into the opening of the silicon pattern 25, and a second gate electrode 28 is disposed over the first gate electrode 27A. A gate insulating pattern 26A is interposed between the first gate electrode 27A and the substrate 21, and between the first gate electrode 27A and the silicon pattern 25. The first gate electrode 27A may include polysilicon, and the second gate electrode 28 may include a metal such as tungsten or a metal silicide such as tungsten silicide. The silicon pattern 25 is a thin film formed through an epitaxial growth, a chemical vapor deposition (CVD), a physical vapor deposition (PVD) process, etc. Hereinafter, the first gate electrode 27A and the second gate electrode 28 are referred to as the patterned first gate conductive layer 27A and the patterned second gate conductive layer 28, respectively, since the first gate electrode 27A and the second gate electrode 28 include a conductive material.

As described above, since a stacked recess gate RG configured with the gate insulating pattern 26A, the patterned first gate conductive layer 27A and the patterned second gate conductive layer 28 is formed on the silicon oxide pattern 25 having the opening, it is possible to realize the recess gate RG without a direct recess etch of the substrate 21. Accordingly, it is possible to increase a length of a channel CH and further prevent dangling bonds and etch damage of the substrate 21.

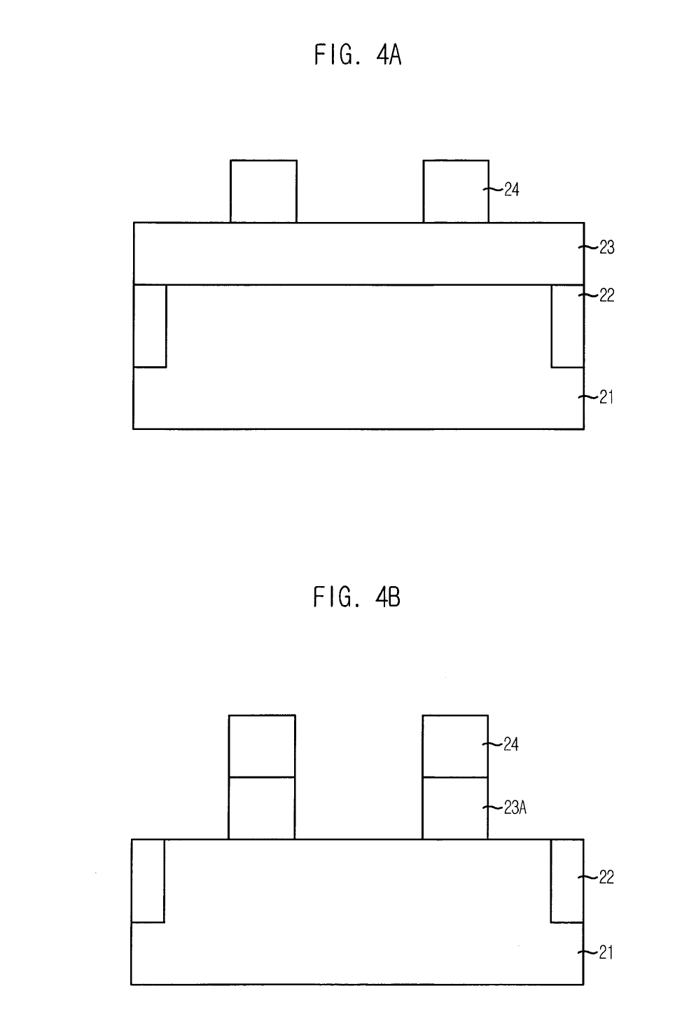

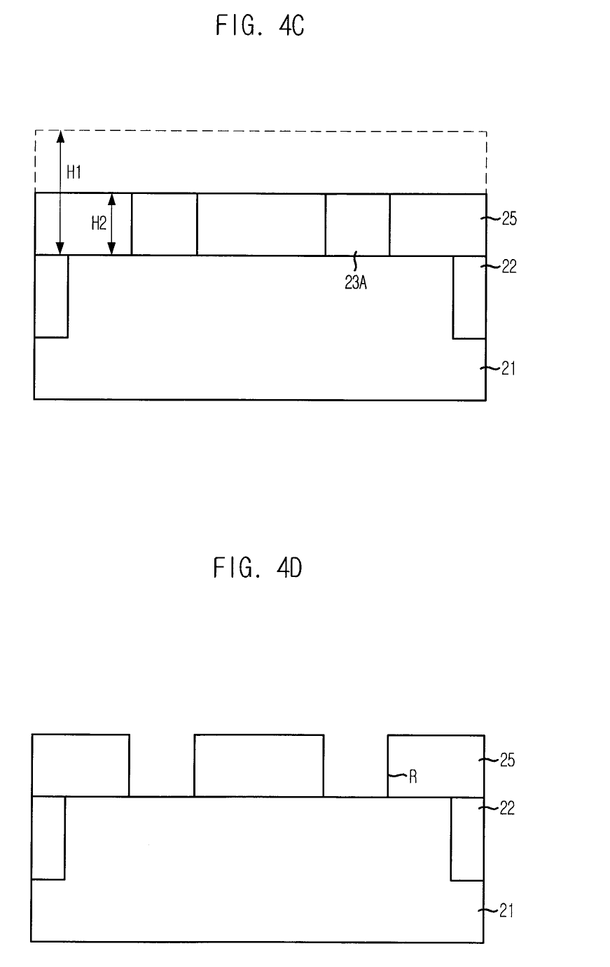

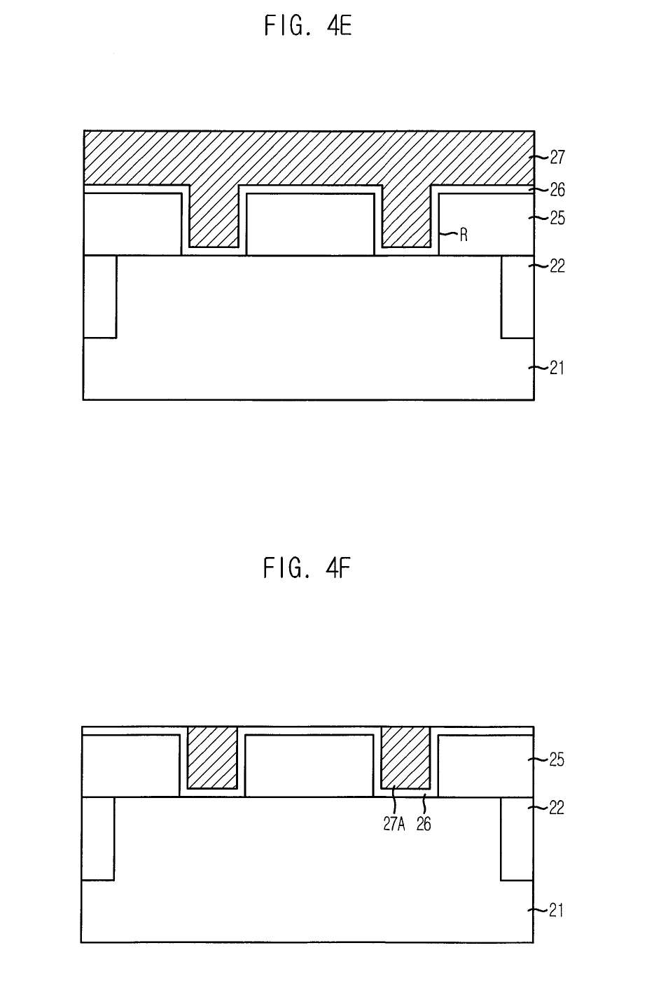

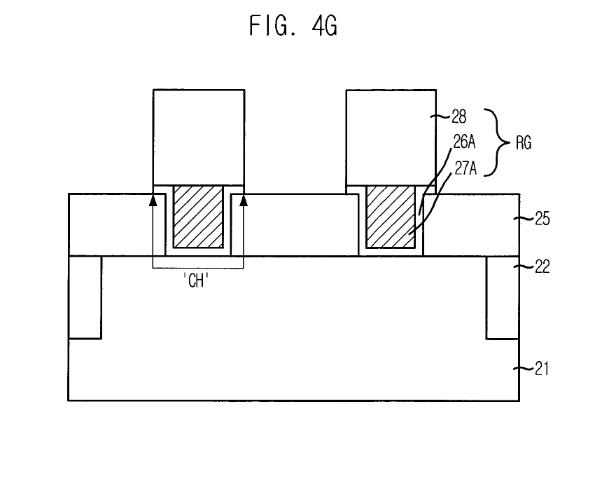

FIGS. 4A to 4G illustrate cross-sectional views showing a method for fabricating the semiconductor device with the recess gate in accordance with some embodiments of the present invention.

Referring to FIG. 4A, a device isolation structure 22 is formed in a given region of substrate 21. The device isolation structure 22 may be formed, for example, using a shallow trench isolation (STI) process. A sacrificial layer 23 is deposited on the substrate 21. The sacrificial layer 23 may include oxide. A photoresist pattern 24 is formed on the sacrificial layer 23. In a plan view, the photoresist pattern 24 is formed only over the region where a gate will be formed. The photoresist pattern 24 may be formed using a light source such as KrF or ArF excimer laser, and have a linewidth of at least approximately 25 nm or greater and a thickness of approximately 20 Å, after a mask process is performed.

Referring to FIG. 4B, the sacrificial layer 23 (see FIG. 4A) is etched using the photoresist pattern 24 as an etch barrier to form a sacrificial pattern 23A. Referring to FIG. 4C, a semiconductive layer is formed over the resultant structure including the sacrificial pattern 23A and the substrate 21. The semiconductive layer includes silicon, and is referred to as the silicon layer hereinafter. The silicon layer may be formed using one process selected from a group consisting of an epitaxial growth process, a CVD process, and a PVD process. In particular, a silicon layer formed by the epitaxial growth process has a similar characteristic as the silicon substrate, i.e., the substrate 21. The silicon layer is formed to a certain thickness that the silicon layer covers the sacrificial pattern 23A. The silicon layer may be formed to a thickness H1. The thickness H1 refers to a thickness of approximately 100 Å or greater.

A planarization process is performed until a top surface of the sacrificial pattern 23A is exposed, thereby reducing the thickness H1 of the silicon layer. The planarization process may be performed using a typical chemical mechanical polishing (CMP) process. The silicon layer is polished by a thickness of approximately 20 Å or greater using the CMP process for at least approximately 3 seconds. After the planarization, a silicon pattern 25 having a thickness H2 is formed, the thickness H2 being substantially the same to that of the sacrificial pattern 23A.

Referring to FIG. 4D, the sacrificial pattern 23A is removed to form an opening R which corresponds to a region where a subsequent gate conductive layer will be formed. Here, the opening R will act as a typical recess formed by selectively etching the substrate using a recess mask. Therefore, in accordance with the present invention, it is possible to obtain a recess structure without a limitation such as a dangling bond. Meanwhile, the sacrificial pattern 23A can be removed by wet etch or dry etch. Herein, only the sacrificial pattern 23A can be selectively removed without an etch loss of the silicon pattern 25.

Referring to FIG. 4E, a gate insulating layer 26 is formed along the opening R and a surface of the substrate 21. The gate insulating layer 26 may include an oxide layer formed by using a thermal oxidation, a dry oxidation, or a wet oxidation. A first gate conductive layer 27 is deposited to a thickness of approximately 30 Å such that the first gate conductive layer 27 fills the opening R. The first gate conductive layer 27 is formed of polysilicon.

Referring to FIG. 4F, the first gate conductive layer 27 is planarized until the gate insulating layer 26 is exposed to form a patterned first gate conductive layer 27A. This planarization process is performed using the CMP process for at least approximately 3 seconds. In addition to the CMP process, an etch-back process may be performed for planarizing the first gate conductive layer 27 using the dry etch or wet etch process. In this case, since the gate insulating layer 26 may be damaged during the planarization process, the gate insulating layer 26 may be grown again.

Referring to FIG. 4G, a second gate conductive layer is formed over the patterned first gate conductive layer 27A. A gate patterning process is performed to form a recess gate RG in which a gate insulating pattern 26A, the patterned first gate conductive layer 27A and a patterned second gate conductive layer 28 are stacked in sequence. A channel CH is formed along a profile of the opening R.

As described above, in accordance with the present invention, a recess gate is not formed by directly etching the substrate but formed by using the oxide-based sacrificial pattern having the opening. That is, after forming the sacrificial pattern having the opening corresponding to the region where the recess gate will be formed, the silicon layer having the similar characteristic as the substrate is formed. Thereafter, the sacrificial pattern is removed, and the gate is then formed over the opening, which makes it possible to form the recess gate without the direct etch of the substrate. Accordingly, it is possible to prevent the dangling bonds and etch damage of the substrate.

While the present invention has been described with respect to the specific embodiments, it will be apparent to those skilled in the art that various changes and modifications may be made without departing from the spirit and scope of the invention as defined in the following claims.

1-5. (canceled)

6. A method of fabricating a semiconductor device with a recess gate, the method comprising:
forming a sacrificial pattern over a given region of a substrate;
forming a semiconductive layer on the resultant structure including the sacrificial pattern;
planarizing the semiconductive layer until the sacrificial pattern is exposed;
removing the sacrificial pattern to form an opening;
forming a gate insulating layer in the opening and over the substrate;
forming a gate conductive layer over the gate insulating layer; and
planarizing the gate conductive layer until the gate insulating layer is exposed.

7. The method of claim 6, further comprising forming a metal or metal silicide layer for use as a gate over the gate conductive layer.

8. The method of claim 6, wherein forming a semiconductive layer on the resultant structure including the sacrificial pattern, further comprises forming at least part of the semiconductive layer with a silicon layer using an epitaxial process.

9. The method of claim 7, wherein the semiconductive layer is formed using a process selected from a group consisting of an epitaxial growth, a chemical vapor deposition (CVD) and a physical vapor deposition (PVD) process.

10. The method of claim 6, wherein the semiconductive layer is formed to a thickness of approximately 100 Å or greater.

11. The method of claim 7, wherein the planarizing of the semiconductive layer comprises performing a CMP process.

12. The method of claim 11, wherein the semiconductive layer is polished by approximately 20 Å or greater using the CMP process for at least approximately 3 seconds.

13. The method of claim 6, wherein the planarizing of the gate conductive layer comprises performing a CMP process.

14. The method of claim 13, wherein the planarizing of the gate conductive layer comprises performing an etch-back process.

15. The method of claim 6, wherein the forming a sacrificial pattern comprises forming the sacrificial pattern using an oxide-based material.

16. The method of claim 6, wherein the removing of the sacrificial pattern to form the opening comprises performing a dry etch or a wet etch.

17. The method of claim 13, wherein the forming the gate conductive layer comprises forming the gate conductive layer using a polysilicon layer.
